(19) United States
(12) Patent Application Publication
(10) Pub. No.: US 2025/0218881 A1
(43) Pub. Date: Jul. 3, 2025

(54) LIQUID-BASED METHOD FOR EMBEDDING COMPONENTS IN THICK SUBSTRATES

(71) Applicant: Intel Corporation, Santa Clara, CA (US)

(72) Inventors: Mahdi MOHAMMADIGHALENI, Phoenix, AZ (US); Shayan KAVIANI, Phoenix, AZ (US); Ehsan ZAMANI, Phoenix, AZ (US); Whitney BRYKS, Tempe, AZ (US); Srinivas Venkata Ramanuja PIETAMBARAM, Chandler, AZ (US); Dilan SENEVIRATNE, Phoenix, AZ (US); Elham TAVAKOLI, Phoenix, AZ (US)

(21) Appl. No.: 18/398,648

(22) Filed: Dec. 28, 2023

(51) Int. Cl. H01L 23/24; H01L 21/56; H01L 23/00; H01L 23/31; H01L 23/48; H01L 25/065

(52) U.S. Cl. CPC H01L 23/24; H01L 21/563; H01L 23/3128; H01L 23/481; H01L 24/16; H01L 25/0655; H01L 2224/16225

(57) ABSTRACT

Embodiments disclosed herein include components embedded in a core of a package substrate. Embodiments disclosed herein may include an apparatus that comprises a substrate with a cavity through a thickness of the substrate. In an embodiment, a component is in the cavity, and a first layer is in the cavity and contacts a sidewall of the component. In an embodiment, the first layer comprises a first material composition. In an embodiment, a second layer is over the first layer, and the second layer comprises a second material composition that is different than the first material composition.

### BACKGROUND

As advanced packaging is enabling more aggressive computation capability, high power and high quality power delivery is needed to support all of the overlying chiplets. Accordingly, the ability to embed passive components (e.g., capacitors, inductors, resistors, etc.) into the package substrate will enable improved performance compared to placing the passive components on the land side of the package. Embedding components in the core is beneficial because there is less routing in the core compared to overlying and underlying buildup layers. As such, space within the package substrate is more fully utilized.

However, substrate core thickness is defined by the total package thermomechanical stress level. This required thickness can be significantly different than the thickness of the passive component. For example, in the case of a deep trench capacitor (DTC), the DTC is fabricated on a silicon wafer. The wafer will have a thickness that is potentially hundreds of microns different than the thickness of the core, which can be approximately 1.0 mm or greater. Placing such passive components in deep cavities through the core can be problematic. For example, the passive components may shift or rotate during embedding. Additionally, filling the small gaps between sidewalls of the cavity and the sidewall of the passive component is difficult. Voids may be present, which can lead to reliability issues for the electronic package.

### BRIEF DESCRIPTION OF THE DRAWINGS

FIG. 1A is a cross-sectional illustration of a core with an embedded passive component that has shifted during the embedding process, in accordance with an embodiment.

FIG. 1B is a cross-sectional illustration of a core with an embedded passive component that has voids between the sidewall of the passive component and the sidewall of the cavity, in accordance with an embodiment.

FIG. 2A is a cross-sectional illustration of a core with a cavity that includes a component that is embedded in the cavity by a first layer and a second layer, in accordance with an embodiment.

FIG. 2B is a cross-sectional illustration of a core with a cavity that includes a component that is embedded in the cavity by a first layer, in accordance with an embodiment.

FIG. 2C is a cross-sectional illustration of a core with a cavity that includes a component that is partially embedded by a first layer and partially embedded by a second layer, in accordance with an embodiment.

FIG. 2D is a cross-sectional illustration of a core with a cavity that includes a plurality of components that are embedded in the cavity by a first layer and a second layer, in accordance with an embodiment.

FIG. 2E is a cross-sectional illustration of a core with a cavity that includes a plurality of components with different thicknesses that are embedded by a first layer and a second layer, in accordance with an embodiment.

FIG. 2F is a cross-sectional illustration of a core with a plurality of cavities with an embedded component in each of the cavities, in accordance with an embodiment.

FIGS. 3A-3F are cross-sectional illustrations depicting a process for forming a core with an integrated component that is embedded in a first layer and a second layer, in accordance with an embodiment.

FIG. 3G is a process flow diagram of a process for assembling a core with an embedded component, in accordance with an embodiment.

FIG. 4 is a cross-sectional illustration of a package substrate that comprises a core with a component that is embedded in a first layer and a second layer, in accordance with an embodiment.

FIG. 5 is a cross-sectional illustration of an electronic system that comprises a core with a component embedded in a first layer and a second layer, in accordance with an embodiment.

FIG. 6 is a schematic of a computing device built in accordance with an embodiment.

### EMBODIMENTS OF THE PRESENT DISCLOSURE

Described herein are electronic systems, and more particularly, components embedded in a deep cavity using a liquid fill material, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

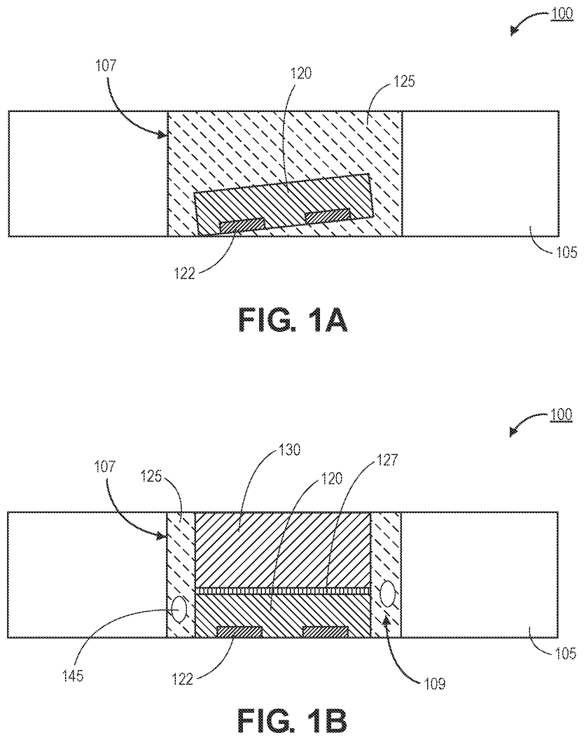

As noted above, introducing passive components (e.g., inductors, capacitors, resistors, etc.) into the package substrate is desirable to improve power delivery and performance for the overlying chiplets compared to placing the passive components on the land side of the package substrate. This is due, at least in part, to the passive components being physically closer to the chiplets when they are integrated into the package substrate. One suitable location in the package substrate for the passive components is the core. The core has underutilized space that can be leveraged to house the passive components. However, the thickness of the passive components is usually smaller than a thickness of the core. This can lead to integration and manufacturing issues. Examples of these drawbacks can be seen in FIGS. 1A and 1B.

Referring now to FIG. 1A, a cross-sectional illustration of a portion of a package substrate 100 is shown, in accordance with an embodiment. The package substrate 100 may comprise a core 105. The core 105 may sometimes be referred to simply as a substrate. The core 105 may be a glass core, an organic core, or the like. In an embodiment, a cavity 107 passes at least partially through the core 105. For example, in FIG. 1A the cavity 107 passes entirely through the core 105.

In an embodiment, a component 120 is provided in the cavity 107. The component 120 may have a thickness that is smaller than a thickness of the core 105. For example, the component 120 may have a thickness that is hundreds of microns thinner than the core 105. The component 120 is secured within the cavity 107 through the use of a fill layer 125. The fill layer 125 may be a dielectric material, such as a mold layer, an epoxy, an adhesive, or the like. However, during the filling process, the component 120 may shift and/or rotate. The movement of the component 120 may be due, at least in part, to the introduction of pressure to the component 120 during the filling process. As shown, the component 120 has tilted so that one side is raised up from the bottom of the core 105. This may make it difficult to make electrical contact to the pads 122 that are at the bottom of the component 120 in subsequent processing operations.

In order to combat the shifting of the component 120, a dummy structure 130 may be added, as shown in FIG. 1B. In an embodiment, the dummy structure 130 is adhered to the component 120 by a layer 127, such as an adhesive material. The dummy structure 130 may provide additional thickness to the component 120 so that the combined thickness is substantially equal to the thickness of the core 105. However, increasing the total thickness of the component 120 and dummy structure 130 device leads to high aspect ratio gaps 109 between sidewalls of the device and the sidewalls of the cavity 107. These high aspect ratio gaps 109 are difficult to fill with traditional filling processes. As such, voids 145 may be generated in the gaps 109. The voids 145 can lead to reliability issues for the package substrate 100.

Accordingly, embodiments disclosed herein reduce movement of the component 120 by securing the component 120 prior to application of pressure. This may be done by dispensing a curable liquid material around the component 120 in the cavity 107. The curable liquid can have a viscosity that enables flowing around the component 120 to fill small gaps 109. After the liquid material is dispensed, a curing process may be implemented. The curing process renders the liquid material a solid, and the component 120 is essentially locked in place. Subsequent molding or lamination processes may then be implemented in order to fill a remainder of the cavity 107.

In order to improve reliability, the curable liquid may be a low coefficient of thermal expansion (CTE) material. For example, the CTE of the cured material may be within 20% of the CTE of the core 105. As such, CTE mismatch is mitigated. In a particular embodiment, the curable liquid may comprise a polymer, such as polyimide or the like.

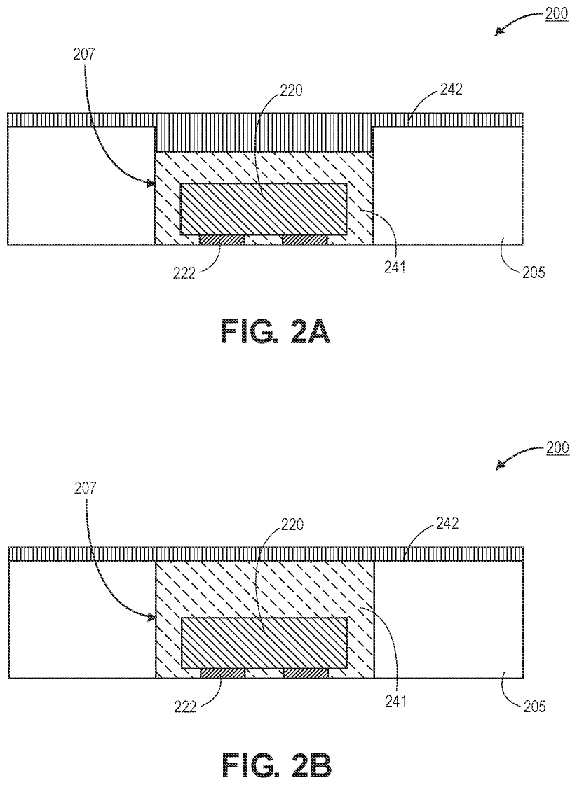

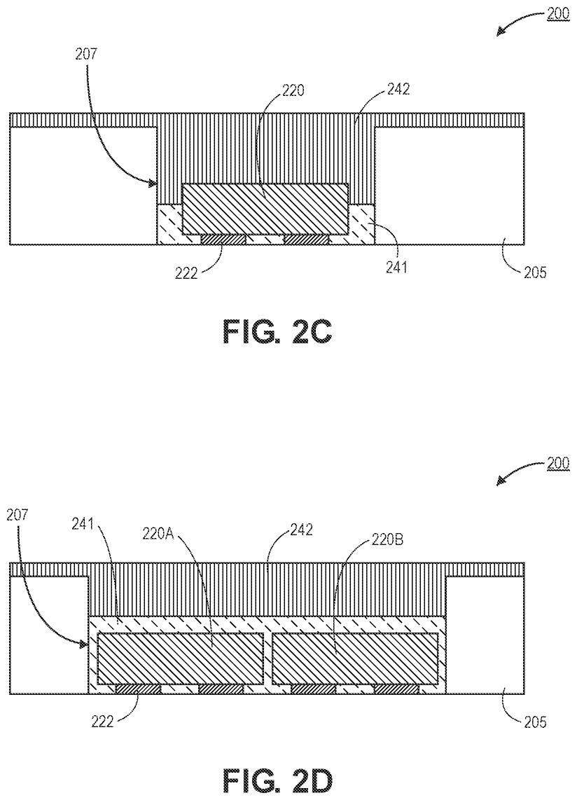

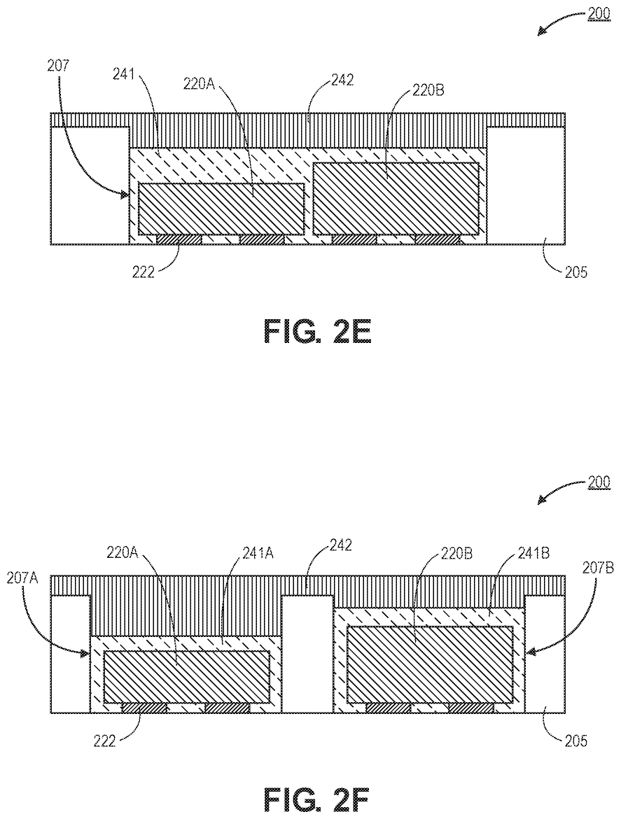

Referring now to FIG. 2A, a cross-sectional illustration of a portion of a package substrate 200 is shown, in accordance with an embodiment. The package substrate 200 may comprise a core 205. The core 205 may comprise any suitable core material, such as a glass core or an organic core with embedded fibers. In the case of a glass core 205, the core 205 may be substantially all glass. The core 205 may be a solid mass comprising a glass material with an amorphous crystal structure where the solid glass core may also include various structures—such as vias, cavities, channels, or other features—that are filled with one or more other materials (e.g., metals, metal alloys, dielectric materials, etc.). As such, core 205 may be distinguished from, for example, the “prepreg” or “RF4” core of a Printed Circuit Board (PCB) substrate which typically comprises glass fibers embedded in a resinous organic material, such as an epoxy. The core 205 may have any suitable dimensions. In a particular embodiment, the core 205 may have a thickness that is approximately 50 μm or greater. For example, the thickness of the core 205 may be between approximately 50 μm and approximately 1.4 mm. Though, smaller or larger thicknesses may also be used. The core 205 may have edge dimensions (e.g., length, width, etc.) that are approximately 10 mm or greater. For example, edge dimensions may be between approximately 10 mm to approximately 250 mm. Though, larger or smaller edge dimensions may also be used. More generally, the area dimensions of the core 205 (from an overhead plan view) may be between approximately 10 mm×10 mm and approximately 250 mm×250 mm. In an embodiment, the core 205 may have a first side that is perpendicular or orthogonal to a second side. In a more general embodiment, the core 205 may comprise a rectangular prism volume with sections (e.g., vias) removed and filled with other materials (e.g., metal, etc.).

The core 205 may comprise a single monolithic layer of glass. In other embodiments, the core 205 may comprise two or more discrete layers of glass that are stacked over each other. The discrete layers of glass may be provided in direct contact with each other, or the discrete layers of glass may be mechanically coupled to each other by an adhesive or the like. The discrete layers of glass in the core 205 may each have a thickness less than approximately 50 μm. For example, discrete layers of glass in the core 205 may have thicknesses between approximately 25 μm and approximately 50 μm. Though, discrete layers of glass may have larger or smaller thicknesses in some embodiments. As used herein, “approximately” may refer to a range of values within ten percent of the stated value. For example approximately 50 μm may refer to a range between 45 μm and 55 μm.

The core 205 may be any suitable glass formulation that has the necessary mechanical robustness and compatibility with semiconductor packaging manufacturing and assembly processes. For example, the core 205 may comprise aluminosilicate glass, borosilicate glass, alumino-borosilicate glass, silica, fused silica, or the like. In some embodiments, the core 205 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, or Zn. More generally, the core 205 may comprise silicon and oxygen, as well as any one or more of aluminum, boron, magnesium, calcium, barium, tin, sodium, potassium, strontium, phosphorus, zirconium, lithium, titanium, or zinc. In an embodiment, the core 205 may comprise at least 23 percent silicon (by weight) and at least 26 percent oxygen (by weight). In some embodiments, the core 205 may further comprise at least 5 percent aluminum (by weight).

In an embodiment, a cavity 207 may be provided at least partially through a thickness of the core 205. In the illustrated embodiment, the cavity 207 passes entirely through the thickness of the core 205. The cavity 207 may have substantially vertical sidewalls. In other embodiments, the cavity 207 may have sloped or otherwise tapered sidewalls. For example, a top of the cavity 207 may be wider than a bottom of the cavity 207 in some embodiments.

In an embodiment, a component 220 is inserted into the cavity 207. The component 220 may comprise an electrical component. More particularly, the component 220 may be a passive electrical component, such as an inductor, a capacitor, a resistor, or the like. The component 220 may be formed on a substrate, such as a semiconductor substrate (e.g., silicon). For example, a deep trench capacitor (DTC) may include capacitive plates that fill trenches formed into a surface of a silicon substrate. The component 220 may have pads 222. The pads 222 may extend out from the component 220. In other embodiments, the component 220 may have a surface that is substantially coplanar with the bottom surface of the pads 222. The pads 222 may be substantially coplanar with the bottom of the core 205. As used herein “substantially coplanar” may refer to two surfaces that are within approximately 10 μm of being coplanar with each other.

In an embodiment, the component 220 may have a thickness that is less than a thickness of the core 205. For example, the thickness of the component 220 may be up to approximately 50 μm smaller than the thickness of the core 205, up to approximately 200 μm smaller than the thickness of the core 205, up to approximately 500 μm smaller than the thickness of the core 205, up to approximately 1 mm smaller than the thickness of the core 205, or any other difference in thickness. In an embodiment, the component 220 may have a thickness that is up to 90% of a thickness of the core 205, up to approximately 50% of the thickness of the core 205, or up to approximately 15% of the thickness of the core 205.

In an embodiment, the component 220 may be at least partially embedded by a first layer 241. The first layer 241 may be a polymeric material that is capable of being dispensed in a liquid form (as will be described in greater detail below). After dispensing, the first layer 241 is cured so that it is rendered a solid material that can secure the component 220 in place. The first layer 241 may be dielectric material in some embodiments. In an embodiment, the first layer 241 may be a low-CTE material. That is, a CTE of the first layer 241 may be approximately 5 ppm/° C. or lower, or approximately 2 ppm/° C. or lower. The first layer 241 may comprise a polymer, such as a polyimide or the like.

The first layer 241 may contact sidewall surfaces, a top surface, and a bottom surface of the component 220. A thickness of the first layer 241 may be greater than a thickness of the component 220. In such an embodiment, the component 220 may be considered as being completely embedded by the first layer 241 since all surfaces of the component 220 are contacted by the first layer 241.

In an embodiment, the first layer 241 may not completely fill the remainder of the cavity 207 that is not occupied by the component 220. The remainder of the cavity 207 may be occupied by a second layer 242. In an embodiment, the second layer 242 is a different material composition than the first layer 241. The second layer 242 may also be a traditional molding material or buildup film material. In an embodiment, the second layer 242 may comprise a CTE that is higher than the CTE of the first layer. Since the component 220 is secured in place by the first layer 241, pressure or other force can be applied into the cavity 207 during the application of the second layer 242. For example, the second layer 242 may be applied with a molding process, a lamination process, or the like. In an embodiment, a first portion of the second layer 242 fills an upper region of the cavity 207, and a second portion of the second layer 242 is disposed over a top surface of the core 205.

In an embodiment, a thickness of the first layer 241 may be different than a thickness of the first portion of the second layer 242 within the cavity 207. For example, the first layer 241 may be thicker than the first portion of the second layer 242. Though, the opposite may also be true in some embodiments as well. In an embodiment, an interface between the first layer 241 and the second layer 242 may be a substantially linear surface. Further, the interface may be substantially parallel to a top or bottom surface of the core 205.

Referring now to FIG. 2B, a cross-sectional illustration of a portion of a package substrate 200 is shown, in accordance with an embodiment. The package substrate 200 in FIG. 2B may be similar to the package substrate 200 in FIG. 2A, with the exception of the structure within the cavity 207. In an embodiment, a component 220 with pads 222 is provided at a bottom of the cavity 207. However, instead of having a double layer fill structure within the cavity 207, the first layer 241 fills substantially all of the cavity 207 not occupied by the component 220 and the pads 222. The first layer 241 may be a curable liquid material, similar to the first layer 241 described above with respect to FIG. 2A. As such, the liquid can be dispensed to fill the cavity 207, and the liquid can be cured to form the first layer 241 in order to secure the component 220 in place.

In an embodiment, the liquid dispensing process may be slower than a molding or laminating process. As such, embodiments with a cavity 207 that is fully filled with the first layer 241 may be suitable when the volume of the cavity 207 is not much larger than a volume of the component 220. As such, not as much liquid needs to be dispensed and the process can be done faster. However, some designs may use a cavity 207 fully filled with the first layer 241 even when the volume of the component 220 is significantly smaller than the volume of the cavity 207. For example, improvements in CTE matching, void free construction, and/or the like may outweigh the slower manufacturing process.

In an embodiment, a second layer 242 may be provided over the first layer 241. The second layer 242 may be applied with a molding process, a lamination process, or the like. Additional pressure or force applied to the component 220 will not cause shifting because the first layer 241 secures the component 220 in place. The second layer 242 may contact both the core 205 and the first layer 241. Since the second layer 242 does not fill a portion of the cavity 207, the outer surfaces of the second layer 242 may define a substantially rectangular cross-section.

Referring now to FIG. 2C, a cross-sectional illustration of a portion of a package substrate 200 is shown, in accordance with an additional embodiment. The package substrate 200 in FIG. 2C may be similar to the package substrate 200 in FIG. 2A, with the exception of the cavity 207 region. Instead of having a first layer 241 that fully embeds the component 220, the first layer 241 may only contact a sidewall of the component 220. The first layer 241 may also contact a bottom surface of the component 220 (i.e., the surface with the pads 222). In the illustrated embodiment, the first layer 241 contacts only a lower portion of the sidewall of the component 220. However, the first layer 241 may still sufficiently retain the component 220 to prevent movement during subsequent processing operations. In such an embodiment, a thickness of the first layer 241 may be less than a thickness of the component 220. Reducing the thickness of the first layer 241 may be useful in reducing the time required to deposit the first layer 241 into the cavity 207. As such, throughput may be improved. In an embodiment, the second layer 242 fills a remainder of the cavity 207. For example, the second layer 242 may contact a sidewall of the component 220 and a top surface of the component 220.

Referring now to FIG. 2D, a cross-sectional illustration of a portion of a package substrate 200 is shown, in accordance with an additional embodiment. The package substrate 200 in FIG. 2D may be similar to the package substrate 200 in FIG. 2A, with the exception of the cavity 207 region. For example, the cavity 207 in FIG. 2D may be sized to accommodate a plurality of components 220. For example, two components 220A and 220B are inserted into the cavity 207. The components 220A and 220B may be similar to each other. That is, the component 220A and the component 220B may both be the same type of passive device (e.g., inductor, capacitor, resistor, etc.). Though, in other embodiments the component 220A may be different than the component 220B.

In FIG. 2D, the component 220A and the component 220B may have substantially the same thickness. As such, a top surface of the first layer 241 may be an equal distance to both the component 220A and the component 220B. The first layer 241 may also be able to be dispensed between sidewalls of the components 220A and 220B. Particularly, since a liquid based deposition process is used, the first layer 241 may fill fine gaps. Accordingly, the components 220A and 220B may be closely spaced to each other, which allows for an increase in component 220 density.

Referring now to FIG. 2E, a cross-sectional illustration of a portion of a package substrate 200 is shown, in accordance with an additional embodiment. The package substrate 200 in FIG. 2E may be similar to the package substrate 200 in FIG. 2D, with the exception of the components 220A and 220B. Instead of being similar to each other, the components 220A and 220B in FIG. 2E have different thicknesses. The difference in thickness may arise from the components 220 being different types of passives, or by being the same type of passive with different capacities.

As shown, the first layer 241 fills the bottom portion of the cavity 207 and fully embeds both components 220A and 220B. Due to the thickness differences, the top surface of the first layer 241 may be closer to the component 220B than the component 220A. In other embodiments, the first layer 241 may fully embed component 220A and component 220B may be partially embedded. That is, the top surface of the component 220B may be above the top surface of the first layer 241.

Referring now to FIG. 2F, a cross-sectional illustration of a portion of a package substrate 200 is shown, in accordance with an embodiment. The package substrate 200 in FIG. 2F may be similar to the package substrate 200 in FIG. 2E, with the exception of the cavity 207. Instead of a single large cavity 207, a first cavity 207A and a second cavity 207B are provided through the core 205. Component 220A may be provided in the first cavity 207A, and component 220B may be provided in the second cavity 207B.

In an embodiment, the component 220A may be fully embedded by first layer 241A, and the component 220B may be fully embedded by first layer 241B. Since the thicknesses of the components 220A and 220B are different, the amount of material for the first layers 241A and 241B may be different as well. More particularly, a top surface of first layer 241A may be at a different height than a top surface of first layer 241B. For example, the top surface of first layer 241B may be above the top surface of first layer 241A. That is, the first layer 241B may be thicker than the first layer 241A in some embodiments.

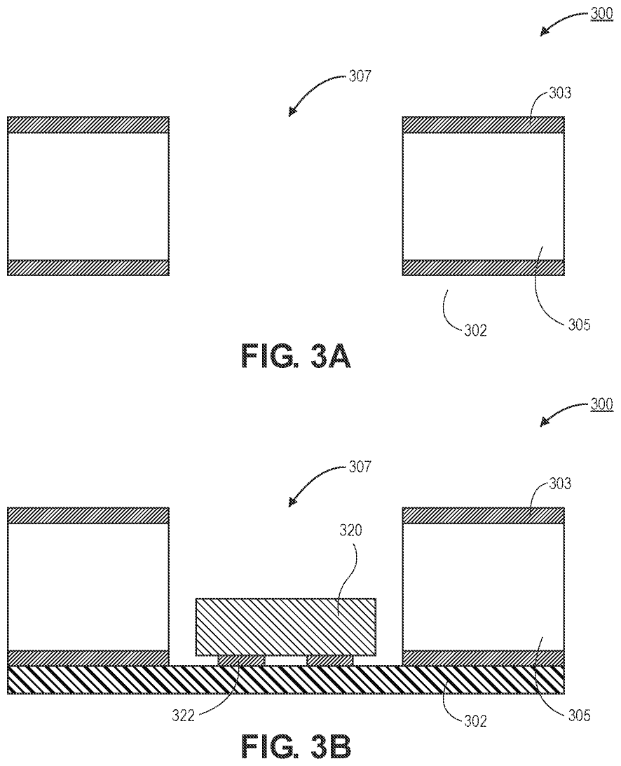

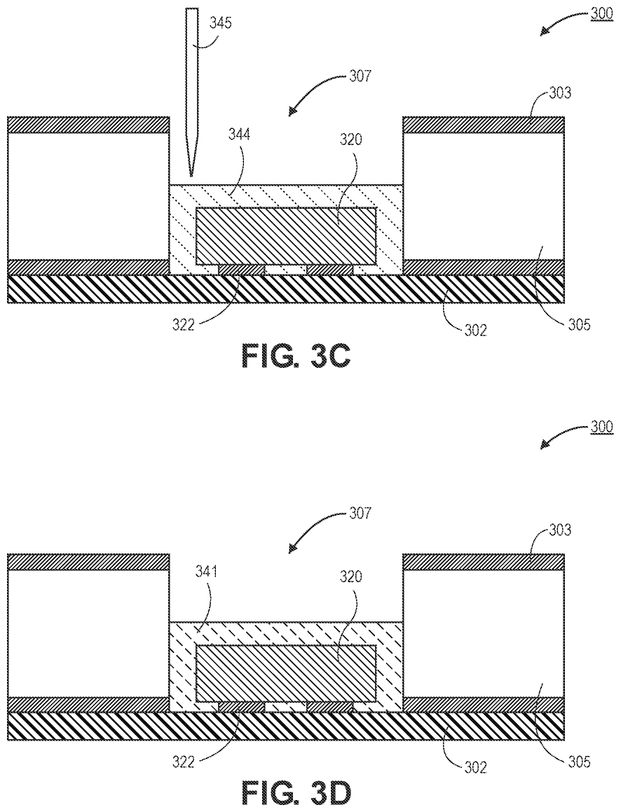

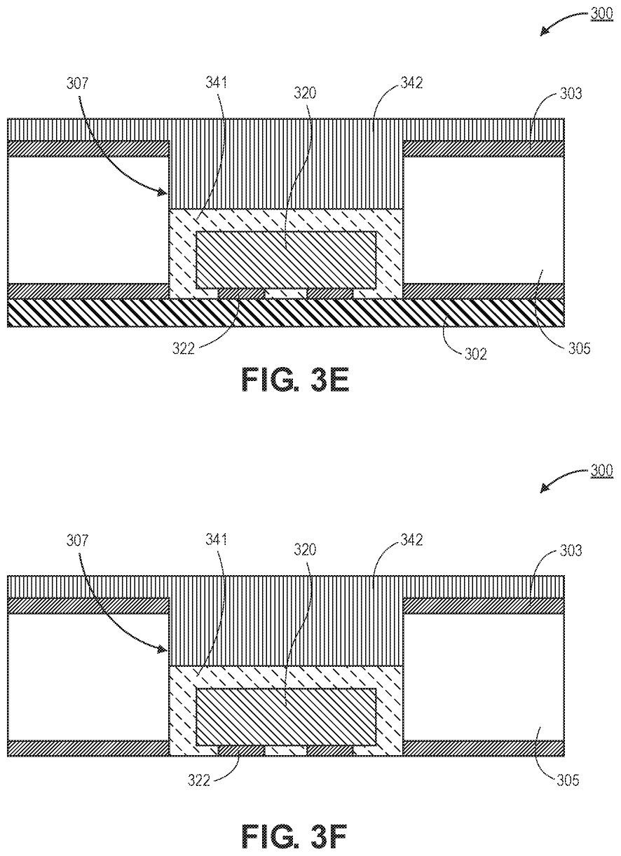

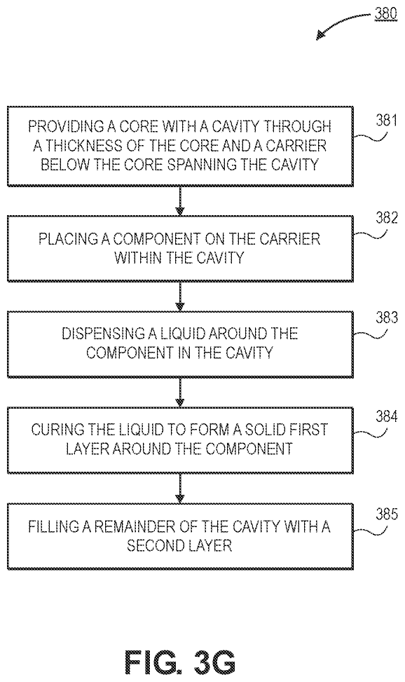

Referring now to FIGS. 3A-3F, a series of cross-sectional illustrations depicting a process for forming a core 305 with an embedded component 320 is shown, in accordance with an embodiment. As shown, a cavity 307 in the core 305 is filled with a fill material that comprises a first layer 341 and a second layer 342. The first layer 341 may be deposited with a liquid based process and cured. This prevents movement of a component 320 that is embedded in the cavity 307.

Referring now to FIG. 3A, a cross-sectional illustration of a portion of a package substrate 300 at a stage of manufacture is shown, in accordance with an embodiment. In an embodiment, the package substrate 300 may comprise a core 305. The core 305 may be an organic core, a glass core, or the like. The core 305 may be similar to any of the cores described in greater detail herein. In an embodiment, cladding 303 may be provided over and/or under the core 305. The cladding 303 may comprise copper or an alternative electrically conductive material.

In an embodiment, a cavity 307 may be provided through at least a portion of a thickness of the core 305 and the cladding 303. As shown in FIG. 3A, the cavity 307 passes entirely through a thickness of the core 305. In an embodiment, the cavity 307 has substantially vertical sidewalls. Though, in other embodiments the cavity 307 may include sloped or otherwise tapered sidewalls.

Referring now to FIG. 3B, a cross-sectional illustration of the portion of the package substrate 300 after a component 320 is added into the cavity 307 is shown, in accordance with an embodiment. As shown, a tape 302 or other carrier substrate (e.g., silicon, glass, ceramic, metal, etc.) is provided below a bottom surface of the core 305. The tape 302 spans across the opening of the cavity 307 in order to provide a surface that can support the component 320. The component 320 may be placed on the tape 302 with a pick-and-place tool, manually, or with any other process. As shown, the pads 322 of the component 320 contact the tape 302. In an embodiment, the component 320 may be similar to any component described in greater detail herein. For example, the component 320 may comprise an inductor, a capacitor, or a resistor in some embodiments. In an embodiment, a thickness of the component 320 may be smaller than a thickness of the core 305.

Referring now to FIG. 3C, a cross-sectional illustration of the portion of the package substrate 300 after a liquid 344 is dispensed into the cavity 307 is shown, in accordance with an embodiment. In an embodiment, the liquid 344 is a curable liquid. That is, the dispensing process may include applying a liquid 344 into the cavity 307 that embeds (or partially embeds) the component 320. After dispensing, the liquid 344 can be cured, as will be described in greater detail below. As such, there is no (or minimal) force applied to the component 320. This prevents the component 320 from moving.

In an embodiment, the liquid 344 can be dispensed with any suitable process. For example, in FIG. 3C a needle 345 is used to dispense the liquid 344 directly into the cavity 307. In other embodiments, other liquid dispensing processes may be used, such as spin coating, squeegeeing, or the like. As shown, the liquid 344 only partially fills the cavity 307. Though, in other embodiments the liquid 344 may fully fill the cavity 307 to provide embodiments similar to those shown in FIG. 2B above.

Referring now to FIG. 3D, a cross-sectional illustration of the portion of the package substrate 300 after a curing process is shown, in accordance with an embodiment. In an embodiment, the curing process converts the liquid 344 into a solid material for the first layer 341. For example, the first layer 341 may be a low-CTE material (similar to other low-CTE materials described herein). In an embodiment, the first layer 341 may be a polymer, such as, but not limited to, a polyimide. In an embodiment, the curing process may include a heat treatment or the like. The thermal energy may drive cross-linking reactions within the liquid 344 that convert the liquid 344 into a solid material. After the first layer 341 has been cured, the component 320 is held in place. This prevents movement of the component 320 during subsequent processing operations.

Referring now to FIG. 3E, a cross-sectional illustration of the portion of the package substrate 300 after a second layer 342 is applied is shown, in accordance with an embodiment. The second layer 342 may be a dielectric material that is different than the first layer 341. For example, the second layer 342 may be a buildup film or any other suitable dielectric material. In an embodiment, the second layer 342 may be applied with a lamination process, a molding process, or the like. Pressure from the deposition process for the second layer 342 does not result in displacement of the component 320 due to the presence of the first layer 341.

In an embodiment, the second layer 342 may fill a portion of the cavity 307. The interface between the first layer 341 and the second layer 342 may be a linear interface that is substantially parallel to a top or bottom surface of the core 305. In an embodiment, the second layer 342 may also cover a top surface of the core 305. For example, the second layer 342 may be directly on the cladding 303 when the cladding 303 is present.

Referring now to FIG. 3F, a cross-sectional illustration of the portion of the package substrate 300 after the tape 302 is removed is shown, in accordance with an embodiment. In an embodiment, the tape 302 may be removed with a peeling process, an etching process, a delamination process, or the like. After the tape 302 is removed, a bottom surface of the first layer 341 may be exposed along the bottom of the core 305. In an embodiment, the bottom surface of the first layer 341 may be substantially coplanar with the bottom surface of the core 305. When the tape 302 has been removed, additional buildup layer patterning processes (not shown) may be used to form the full package substrate 300 with electrical routing (e.g., pads, vias, traces, etc.) and the like.

Referring now to FIG. 3G, a process flow diagram of a process 380 for assembling a core 305 with a component 320 embedded in a cavity 307 is shown, in accordance with an embodiment. In an embodiment, the process 380 may begin with operation 381, which comprises providing a core 305 with a cavity 307 through a thickness of the core 305 and a carrier (or tape) 302 below the core 305 spanning the cavity 307. In an embodiment, operation 381 may be similar to the structure and processes described above with respect to FIG. 3A and a portion of FIG. 3B.

In an embodiment, the process 380 may continue with operation 382, which comprises placing a component 320 on the carrier 302 within the cavity 307. In an embodiment, the operation 382 may be similar to the structure and process described above with respect to FIG. 3B.

In an embodiment, the process 380 may continue with operation 383, which comprises dispensing a liquid 344 around the component 320 in the cavity 307. In an embodiment, the liquid 344 may be dispensed with any suitable liquid dispensing process. The operation 383 may be similar to the structure and process described above with respect to FIG. 3C.

In an embodiment, the process 380 may continue with operation 384, which comprises curing the liquid 344 to form a solid first layer 341 around the component 320. In an embodiment, operation 384 may be similar to the structure and process described above with respect to FIG. 3D.

In an embodiment, the process 380 may continue with operation 385, which comprises filling a remainder of the cavity 307 with a second layer 342. In an embodiment, operation 385 may be similar to the structure and process described above with respect to FIG. 3E. After the second layer 342 is formed, the carrier 302 may be removed, similar to the embodiment shown in FIG. 3F.

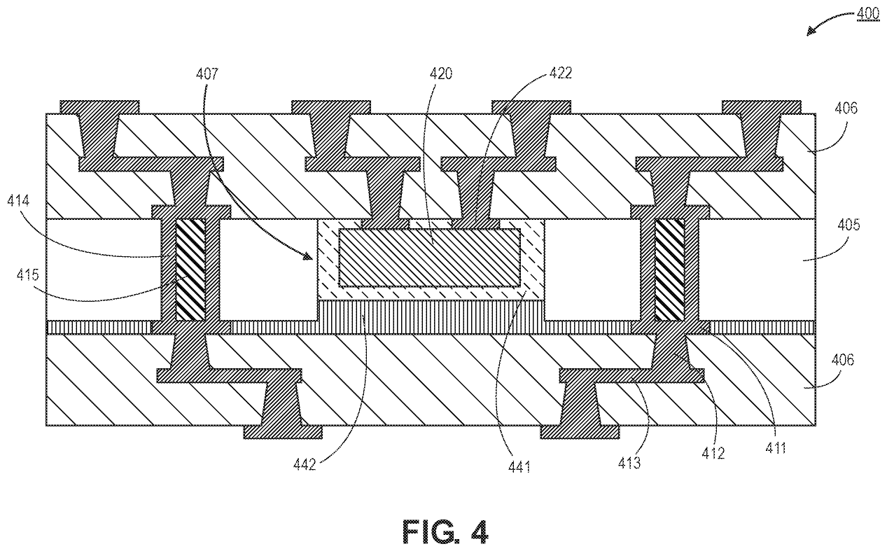

Referring now to FIG. 4, a cross-sectional illustration of a package substrate 400 is shown, in accordance with an embodiment. In the embodiments previously disclosed herein, the core 405 is shown in isolation. However, it is to be appreciated that the package substrate 400 may further include buildup layers 406 over and under the core 405. The buildup layers 406 may include electrical routing (e.g., pas 411, vias 412, traces 413, and the like). Additionally, vias 414 may pass through a thickness of the core 405. The vias 414 may be electrically conductive shells that are filled with an insulating plug 415. In other embodiments, the vias 414 may be solid (fully filled) electrically conductive material.

In an embodiment, a cavity 407 may be provided through a thickness of the core 405. A component 420 may be provided in the cavity 407. The component 420 may be similar to any of the components described herein. For example, the component 420 may include pads 422 to electrically couple passive devices to external structures. In an embodiment, a first layer 441 at least partially embeds the component 420. The first layer 441 may be a low-CTE material that is dispensed in a liquid form and cured to form a solid material. In an embodiment, a second layer 442 may fill a remainder of the cavity 407 and cover a surface of the core 405. While the second layer 442 and the buildup layers 406 are shown with different shading, in some embodiments, the second layer 442 and the buildup layers 406 may be the same material.

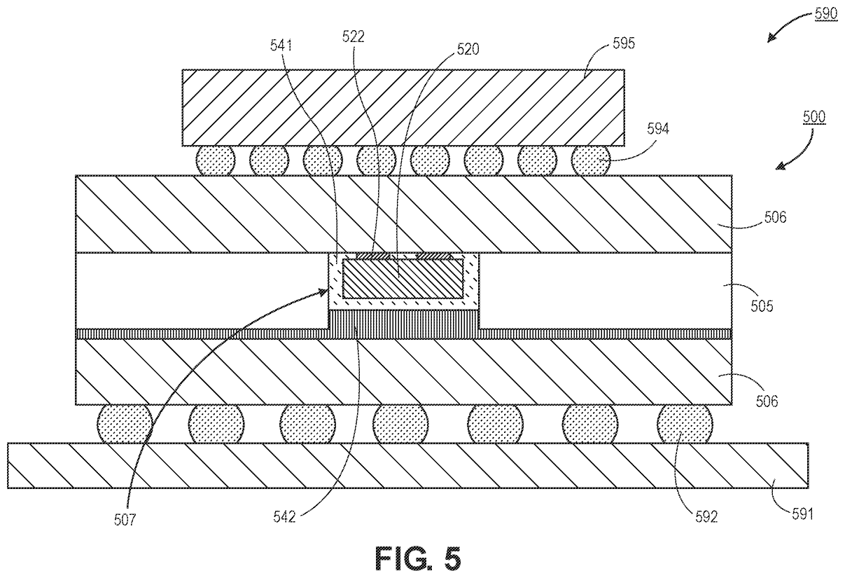

Referring now to FIG. 5, a cross-sectional illustration of an electronic system 590 is shown, in accordance with an embodiment. In an embodiment, the electronic system 590 comprises a board 591, such as a printed circuit board (PCB), a motherboard, or the like. The board 591 may be coupled to a package substrate 500 by interconnects 592. The interconnects 592 may be any second level interconnect (SLI) architecture (e.g., solder balls, sockets, pins, etc.).

In an embodiment, the package substrate 500 may be similar to any of the package substrates described herein. For example, the package substrate 500 may comprise a core 505 with buildup layers 506 over and under the core 505. In an embodiment, a cavity 507 through the core 505 houses a component 520 (e.g., an inductor, a capacitor, a resistor, or the like). In an embodiment, the component 520 may include pads 522 to electrically couple passive devices to external structures. The component 520 may be at least partially embedded in a first layer 541. The first layer 541 may be dispensed as a liquid and cured to form a solid. A second layer 542 may fill a remainder of the cavity 507.

In an embodiment, one or more dies 595 are coupled to the package substrate 500 by interconnects 594. The interconnects 594 may comprise any first level interconnect (FLI) architecture (e.g., solder balls, copper bumps, hybrid bonding interfaces, etc.). In an embodiment, the dies 595 may include any type of die, such as a central processing unit (CPU), a graphics processing unit (GPU), an XPU, a communications die, a memory die, an application specific integrated circuit (ASIC), a field programmable gate array (FPGA), or the like. In an embodiment, the component 520 may be electrically coupled to the die 595 in order to improve and/or control power delivery to the die 595.

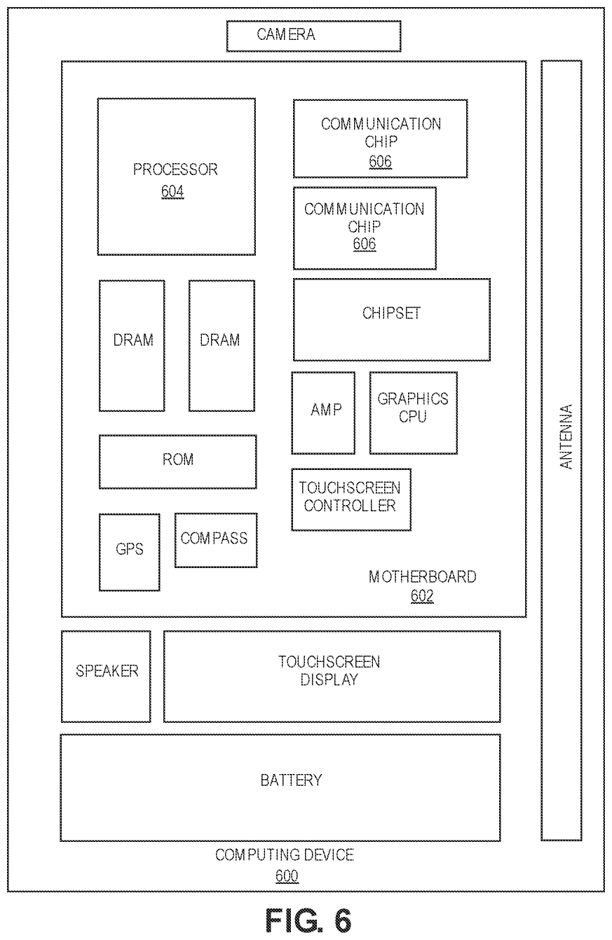

FIG. 6 illustrates a computing device 600 in accordance with one implementation of the disclosure. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In some implementations of the disclosure, the integrated circuit die of the processor may be part of an electronic package that includes a component in a cavity that is embedded in a first layer that is dispensed as a liquid and cured to form a solid, in accordance with embodiments described herein. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another implementation of the disclosure, the integrated circuit die of the communication chip may be part of an electronic package that includes a component in a cavity that is embedded in a first layer that is dispensed as a liquid and cured to form a solid, in accordance with embodiments described herein.

In an embodiment, the computing device 600 may be part of any apparatus. For example, the computing device may be part of a personal computer, a server, a mobile device, a tablet, an automobile, or the like. That is, the computing device 600 is not limited to being used for any particular type of system, and the computing device 600 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.
Example 1: an apparatus, comprising: a substrate; a cavity through a thickness of the substrate; a component in the cavity; a first layer in the cavity that contacts a sidewall of the component, wherein the first layer comprises a first material composition; and a second layer over the first layer, wherein the second layer comprises a second material composition that is different than the first material composition.
Example 2: the apparatus of Example 1, wherein a surface of the component is separated from a surface of the second layer by the first layer.
Example 3: the apparatus of Example 1 or Example 2, wherein the first layer has a top surface that is substantially coplanar with a top surface of the substrate and a bottom surface that is substantially coplanar with a bottom surface of the substrate.
Example 4: the apparatus of Examples 1-3, wherein the first layer comprises a polyimide.
Example 5: the apparatus of Examples 1-4, wherein the first layer has a first coefficient of thermal expansion (CTE), and the second layer has a second CTE that is higher than the first CTE.
Example 6: the apparatus of Examples 1-5, wherein the second layer is a buildup film.
Example 7: the apparatus of Examples 1-6, wherein the second layer at least partially fills the cavity.
Example 8: the apparatus of Examples 1-7, wherein an interface between the first layer and the second layer is substantially parallel to a top surface of the substrate.
Example 9: the apparatus of Examples 1-8, wherein the substrate comprises an organic dielectric with embedded fibers, or wherein the substrate comprises a glass layer with a rectangular prism form factor.
Example 10: the apparatus of Examples 1-9, wherein the component comprises one or more of an inductor, a capacitor, or a resistor.
Example 11: an apparatus, comprising: a core with a cavity that passes through a thickness of the core; a component in the cavity, wherein the core has a first thickness and the component has a second thickness that is smaller than the first thickness; a first layer in the cavity, wherein the first layer has a third thickness that is between the first thickness and the second thickness; and a second layer over the first layer.
Example 12: the apparatus of Example 11, wherein the second layer fills at least a portion of the cavity.
Example 13: the apparatus of Example 12, wherein a portion of the second layer in the cavity has a fourth thickness that is smaller than the third thickness.
Example 14: the apparatus of Examples 11-13, wherein the first thickness is greater than approximately 1.0 mm, and wherein the second thickness is up to approximately 75% of the first thickness.
Example 15: the apparatus of Examples 11-14, wherein the core comprises a glass layer or an organic dielectric.
Example 16: the apparatus of Examples 11-15, wherein the component comprises one or more of an inductor, a capacitor, or a resistor.
Example 17: the apparatus of Examples 11-16, further comprising: a pad coupled to the component, wherein a surface of the pad is substantially coplanar with a surface of the core.
Example 18: an apparatus, comprising: a board; a package substrate coupled to the board, wherein the package substrate comprises: a core with a cavity; a component in the cavity; and a fill layer in the cavity around the component, wherein the fill layer comprises a first material composition in a first region of the cavity and a second material composition is a second region of the cavity, wherein the first material composition is different than the second material composition; and a die coupled to the package substrate.
Example 19: the apparatus of Example 18, wherein the component is in the first region of the cavity.
Example 20: the apparatus of Example 18 or Example 19, wherein the apparatus is part of a personal computer, a server, a mobile device, a tablet, or an automobile.

What is claimed is:

1. An apparatus, comprising:
a substrate;
a cavity through a thickness of the substrate;
a component in the cavity;
a first layer in the cavity that contacts a sidewall of the component, wherein the first layer comprises a first material composition; and
a second layer over the first layer, wherein the second layer comprises a second material composition that is different than the first material composition.

2. The apparatus of claim 1, wherein a surface of the component is separated from a surface of the second layer by the first layer.

3. The apparatus of claim 1, wherein the first layer has a top surface that is substantially coplanar with a top surface of the substrate and a bottom surface that is substantially coplanar with a bottom surface of the substrate.

4. The apparatus of claim 1, wherein the first layer comprises a polyimide.

5. The apparatus of claim 1, wherein the first layer has a first coefficient of thermal expansion (CTE), and the second layer has a second CTE that is higher than the first CTE.

6. The apparatus of claim 1, wherein the second layer is a buildup film.

7. The apparatus of claim 1, wherein the second layer at least partially fills the cavity.

8. The apparatus of claim 1, wherein an interface between the first layer and the second layer is substantially parallel to a top surface of the substrate.

9. The apparatus of claim 1, wherein the substrate comprises an organic dielectric with embedded fibers, or wherein the substrate comprises a glass layer with a rectangular prism form factor.

10. The apparatus of claim 1, wherein the component comprises one or more of an inductor, a capacitor, or a resistor.

11. An apparatus, comprising:
a core with a cavity that passes through a thickness of the core;
a component in the cavity, wherein the core has a first thickness and the component has a second thickness that is smaller than the first thickness;
a first layer in the cavity, wherein the first layer has a third thickness that is between the first thickness and the second thickness; and
a second layer over the first layer.

12. The apparatus of claim 11, wherein the second layer fills at least a portion of the cavity.

13. The apparatus of claim 12, wherein a portion of the second layer in the cavity has a fourth thickness that is smaller than the third thickness.

14. The apparatus of claim 11, wherein the first thickness is greater than approximately 1.0 mm, and wherein the second thickness is up to approximately 75% of the first thickness.

15. The apparatus of claim 11, wherein the core comprises a glass layer or an organic dielectric.

16. The apparatus of claim 11, wherein the component comprises one or more of an inductor, a capacitor, or a resistor.

17. The apparatus of claim 11, further comprising:
a pad coupled to the component, wherein a surface of the pad is substantially coplanar with a surface of the core.

18. An apparatus, comprising:
a board;
a package substrate coupled to the board, wherein the package substrate comprises:
a core with a cavity;
a component in the cavity; and
a fill layer in the cavity around the component, wherein the fill layer comprises a first material composition in a first region of the cavity and a second material composition is a second region of the cavity, wherein the first material composition is different than the second material composition; and
a die coupled to the package substrate.

19. The apparatus of claim 18, wherein the component is in the first region of the cavity.

20. The apparatus of claim 18, wherein the apparatus is part of a personal computer, a server, a mobile device, a tablet, or an automobile.
